(19) United States
(12) Patent Application Publication
(10) Pub. No.: US 2003/0157804 A1
(43) Pub. Date: Aug. 21, 2003

(54) Composition for the chemical mechanical polishing of metal and metal/dielectric structures

(76) Inventors: Lothar Puppe, Burscheid (DE); Gerd Passing, Koln (DE); Ming-Shih Tsai, Hsinchu (TW)

Correspondence Address: BAYER POLYMERS LLC, 100 BAYER ROAD, PITTSBURGH, PA, 15205, US

(21) Appl. No.: 10/322,961

(22) Filed: Dec. 18, 2002

(30) Foreign Application Priority Data
Dec. 27, 2001 (DE) 10164262.8

(51) Int. Cl. H01L 21/302; H01L 21/461

(52) U.S. Cl. 438/692

(57) ABSTRACT

A composition containing −2.5 to 70% by volume of a 30% by weight cationically modified silica sol, the cationically modified SiO₂ particles of which have a mean particle size of 12 to 300 nm, and 0.5 to 22% by weight of at least one oxidizing agent, with pH of 2.5 to 6, is eminently suitable as a polishing slurry for the chemical mechanical polishing of metal and metal/dielectric structures.

### BACKGROUND OF THE INVENTION

1. Field of the Invention

The present invention relates to a composition for the chemical mechanical polishing (CMP) of metal and dielectric structures with a high Cu removal rate, to a process for its production and to its use.

2. Brief Description of the Prior Art

Integrated semiconductor circuits (ICs) comprise structured semiconducting, nonconductive and electrically conductive thin films. These structured films are usually produced by a film material being applied by vapour deposition, for example, and are structured by means of a microlithographic process. The combination of the various semiconducting, nonconductive and conductive layer materials produces the electronic circuit elements of the IC, such as for example transistors, capacitors, resistors and wiring.

The quality of an IC and its function is crucially dependent on the accuracy with which the various layer materials can be applied and structured. However, as the number of layers increases, the planarity of the layers decreases considerably. Beyond a certain number of layers, this leads to one or more functional elements of the IC failing and therefore to the entire IC failing.

The reduction in the planarity of the layers results from the build-up of new layers when these layers have to be applied to layers which have already been structured. The structuring gives rise to differences in height which may amount to up to 0.6 μm per layer. These differences in height are cumulative from layer to layer and mean that the next layer is no longer applied to a planar surface, but rather to a nonplanar surface. A first consequence is that the layer which is subsequently applied has a nonuniform thickness. In extreme cases, flaws and defects are formed in the electronic functional elements and the contacts lack quality. Moreover, uneven surfaces lead to problems with the structuring. To make it possible to produce sufficiently small features, an extremely high imaging accuracy (DOF, depth of focus) is required in the microlithographic process step. However, these structures can only be sharply focused in one plane; the greater certain locations deviate from this plane, the more blurred the imaging becomes.

To solve this problem, the process known as chemical mechanical polishing (CMP) is carried out. CMP results in global planarization of the structured surface by removing elevated parts of the layer until a planar layer is obtained. As a result, the next layer can be built up on a planar surface without height differences, and the precision of structuring and the ability of the elements of the IC to function are retained.

A CMP step is carried out with the aid of special polishing machines, polishing pads and polishing abrasives (polishing slurries). A polishing slurry is a composition which, in combination with the polishing pad on the polishing machine, is responsible for removing the material which is to be polished.

A wafer is a polished disc of silicon on which integrated circuits are built up.

An overview of CMP technology is given, for example, in B. L. Mueller, J. S. Steckenrider Chemtech (1998), pp. 38-46.

Particularly in polishing steps in which semiconductor layers are involved, the demands imposed on the accuracy of the polishing step and therefore on the polishing slurry are particularly high.

A range of parameters which are used to characterize the effect of the polishing slurry are used as an assessment scale for the effectiveness of polishing slurries. These parameters include the abrasion rate, i.e. the rate at which the material which is to be polished is removed, the selectivity, i.e. the ratio of the polishing rates of material which is to be polished with respect to further materials which are present, and also variables relating to the uniformity of planarization. Variables used for the uniformity of the planarization are usually the within wafer non-uniformity (WIWNU) and the wafer to wafer nonuniformity (WTWNU), and also the number of defects per unit area.

What is known as the Cu damascene process is increasingly used for the production of integrated circuits (ICs) (cf. for example “Microchip Fabrication: A Practical Guide to Semiconductor Processing”, Peter Van Zant, 4^{th} ed., McGraw-Hill, 2000, pp 401-403 and 302-309 and “Copper CMP: A Question of Tradeoffs”, Peter Singer, Semiconductor International, Verlag Cahners, May 2000, pp 73-84). In this case, it is necessary for a Cu layer to undergo chemical mechanical polishing with a polishing slurry (the so-called Cu-CMP process), in order for the Cu interconnects to be produced. The finished Cu interconnects are embedded in a dielectric. Between Cu and the dielectric there is a barrier layer. The prior art for the Cu-CMP process is a two-step process, i.e. the Cu layer is firstly polished using a polishing slurry which ensures that a large amount of Cu is removed. Then, a second polishing slurry is used in order to produce the final planar surface with the brightly polished dielectric and the embedded interconnects.

The first polishing step uses a polishing slurry with a high selectivity, i.e. the abrasion rate for Cu is as high as possible and the abrasion rate for the material of the barrier layer below it is as low as possible. The polishing process is stopped automatically as soon as the barrier layer is uncovered below the Cu.

The barrier layer is then removed in a second polishing step. This uses polishing slurries with a high abrasion rate for the barrier layer. The abrasion rate for Cu is less than or equal to the abrasion rate for the barrier layer.

It is known from the prior art for titanium oxide, silicon oxide or aluminium oxide, for example, to be used as abrasives in polishing slurries for the first polishing step (cf. for example WO-A 99/64527, WO-A 99/67056, U.S. Pat. No. 5,575,837 and WO-A 00/00567). A drawback of polishing slurries which contain aluminium oxide is their high hardness, which leads to increased amounts of scratches on the wafer surface. This effect can be reduced if the aluminium oxide is produced using vapour phase processes and not by means of melting processes. This process results in irregular shaped particles which have sintered together from a large number of small primary particles (aggregates). The vapour phase process can also be used for the production of titanium dioxide or silicon dioxide particles. In principle, sharp-edged particles scratch more strongly than round, spherical particles.

Silica sol particles are individual, unagglomerated or unaggregated, round, spherical particles with a negative surface charge. They are amorphous and their density is lower than that of SiO₂ particles which result from vapour phase processes. Accordingly, silica sol particles are softer. Therefore, the grain shape and softness of silica sol particles mean that they offer the best conditions for production of a polishing slurry which does not scratch the soft Cu surface.

It is known from WO-A 99/67056 to use a silica sol which is modified with aluminate ions and is stabilized with Na ions. However, high levels of Na ions in the liquid phase of polishing slurries for the chemical mechanical polishing of integrated circuits are undesirable.

Furthermore, it is known from EP-A 1 000 995 to use cationically modified silica sols for polishing dielectric structures, but without any oxidizing agents being added. There is no mention of metal: barrier layer selectivities.

The polishing slurries which are known from the abovementioned prior art all have the drawback that the selectivities, in particular the metal:barrier layer selectivities, have to be set by means of a combination of a plurality of additives, e.g., film-forming agents or organic compounds, and the metal:barrier layer selectivity, which is only predetermined by the abrasive and pH in the presence of an oxidizing agent, is too low (<20:1). Therefore, the object of the invention was to provide a composition based on silica sol which is improved compared to the prior art and is suitable for the chemical mechanical polishing of metal and metal/dielectric structures, with a high metal removal rate of ≧3000 Å/min. and a metal:barrier layer selectivity of 20:1 or higher.

Surprisingly, it has now been found that this object is achieved by a composition which contains a silica sol with a positive surface charge as abrasive and an oxidizing agent and has an acid pH.

### SUMMARY OF THE INVENTION

Therefore, the subject matter of the invention is a composition containing 2.5 to 70% by volume of a silica sol containing 30% by weight of cationically modified SiO₂, the cationically modified SiO₂ particles of which have a mean particle size of 12 to 300 nm, and 0.05 to 22% by weight of at least one oxidizing agent, with a pH of from 2.5 to 6.

IT WOULD BE ADVISABLE TO STATE A RANGE FOR THE % BY WEIGHT OF THE CATIONICALLY MODIFIED SIO2—IN THE SPECIFICATION AND THE CLAIMS.—SEE THE HIGHLIGHTED SECTION OF PAGE 8

In the context of the present invention, the following definitions of terms apply.

The term metal encompasses the elements W, Al, Cu, Ru, Pt and Ir and/or the alloys, carbides and/or carbonitrides thereof.

The term dielectric encompasses organic and inorganic dielectrics. Examples of organic dielectrics are SiLK™ (Dow Chemical Company), polyimides, fluorinated polyimides, diamond-like carbons, polyarylethers, polyarylenes, parylene N, cyclotenes, polynorbornenes and Teflon. Inorganic dielectrics are based, for example, on SiO₂ glass as the principal constituent. Fluorine, phosphorus, boron and/or carbon may be present as additional constituents. Conventional designations for these dielectrics are, for example, FSG, PSG, BSG or BPSG, where SG represents spin-on-glass. Various fabrication methods are known for the fabrication of these dielectric layers (cf. for example Peter Van Zant, 4^{th} ed., McGraw-Hill, 2000, pp. 363-376 and pp. 389-391). Moreover, silsesquioxanes (HSQ, MSQ) are known as dielectrics which are highly polymerized and are close to the inorganic state.

The term barrier layer encompasses layers of Ta, TaSi, TaN, TaSiN, Ti, TiN, WN, WSiN, SiC, silicon oxynitride, silicon oxycarbide with oxygen as an additional constituent, silicon oxyicarbonitride and/or Si₃N₄.

### DETAILED DESCRIPTION OF THE INVENTION

The silica Sol which is used in the composition according to the invention is a cationically modified sol, comprising an aqueous, acidic suspension of colloidal silica sol, the SiO₂ particles of which are positively charged at the surface. The surface modification can be produced by reaction of unmodified silica sols with soluble, trivalent or tetravalent metal oxides, metal oxychlorides, metal oxyhydrates, metal nitrates, metal sulphates, metal oxysulphates and/or metal oxalates, examples of suitable metals being Al, B, Fe, Ti, Zr, Ga, Mn and/or In. According to the invention, alumina-modified silica sols are preferred. Silica sols of this type are known (cf. for example R. K. Iler, “The Chemistry of Silica”, John Wiley & Sons, pp. 410-411). Examples of counterions are CH₃COO⁻, NO₃⁻, Cl⁻ or SO₄²⁻. CH₃COO⁻ is a preferred counterion. The primary particles of the silica sol are not aggregated or agglomerated.

The cationically modified silica sols which are present in the composition according to the invention may, for example, be produced by first of all dissolving the trivalent or tetravalent metal oxides, metal oxychlorides, metal oxyhydrates, metal nitrates, metal sulphates, metal oxysulphates and/or metal oxalates, preferably aluminium hydroxychloride, in water, then adding acetic acid if required and then mixing it with an alkaline silica sol which is unstabilized or stabilized by sodium or preferably potassium ions, with stirring. The pH of the stable, cationically modified silica sol is between 2.5 and 6. The amount of trivalent or tetravalent metal oxides, metal oxychlorides, metal oxyhydrates, metal nitrates, metal sulphates, metal oxysulphates and/or metal oxalates is preferably such that the surface of the SiO₂ particles is completely covered.

A production variant which is likewise suitable for the cationic silica sol comprises the Al modification being carried out at the alkali metal-stabilized silica sol, followed by a charge transfer using acid ion exchange resins. If appropriate, further amounts of acids may be added to the acidic silica sol in order to set the required pH.

The mean particle size of the cationically modified SiO₂ particles in the silica sol which is to be used in accordance with the invention is 12 to 300 nm, preferably 30 to 200 nm, and more preferably 35 to 90 nm. In this context, the mean particle size is to be understood as meaning the d₅₀ particle size diameter as determined using the ultracentrifuge.

The composition according to the invention generally contains 1 to 21.5% by weight, preferably 3 to 15% by weight and particularly preferably 5 to 10% by weight of cationically modified SiO₂.

RECONCILE THE 21.5% UPPER LIMIT DESCRIBED ABOVE WITH CLAIM 1 WHICH RECITES A SILICA SOL CONTAINING 30% BY WEIGHT OF CATIONICALLY MODIFIED SIO₂.

In a preferred embodiment, the cationically modified silica sol which is present in the composition according to the invention has a multimodal size distribution curve. A known measurement method for determining the modality of a suspension is described in H. G. Müller Colloid Polym. Sci 267; 1989, pp.1113-1116.

The preparation according to the invention particularly preferably contains silica sols which have a bimodal particle size distribution, the maximum A (d₅₀A) of the bimodal particle size distribution preferably lying in the range from 10-100 nm, the maximum B (d₅₀B) in the range from 40-300 nm, and the maximum A+10 nm<maximum B.

The bimodal silica sol which is preferably used in the composition according to the invention is preferably produced by mixing monomodal silica sols. The bimodal silica sol may be produced directly during the silica sol synthesis.

The surface modification by means of trivalent or tetravalent metal oxides may be carried out before or after the mixing of the silica sols. Examples of suitable oxidizing agents for the composition according to the invention are HNO₃, AgNO₃, CuClO₄, H₂SO₄, H₂O₂, HOCl, KMnO₄, ammonium peroxodisulphate, KHSO₅, ammonium oxalate, Na₂CrO₄, UHP, Fe perchlorate, Fe chloride, Fe citrate, Fe nitrate, HlO₃, KlO₃ or HClO₃. Hydrogen peroxide and ammonium peroxodisulphate are preferred. The composition according to the invention preferably contains 0.05 to 22% by weight of at least one oxidizing agent.

In a preferred embodiment of the invention, the composition contains 3 to 15% by volume of hydrogen peroxide. It is particularly preferable for the composition to contain 5 to 12% by volume, and very particularly preferably 7 to 10% by volume, of hydrogen peroxide. Since it is easier to handle, the hydrogen peroxide in the composition according to the invention may also be added in the form of dilute hydrogen peroxide solutions.

In an embodiment which is likewise preferred, the composition according to the invention contains 0.01-6% by weight of ammonium peroxodisulphate as oxidizing agent.

The pH of the composition according to the invention is in the range from 2.5 to 6. The range from 3 to 5 is preferred, and the range from 3.5 to 4.5 is very particularly preferred. The pH of the composition is generally set by adding a base to the silica sol. The amount of base depends on the desired pH. Examples of suitable bases are KOH, guanidine and/or guanidine carbonate. The pH of the composition is preferably set by adding an aqueous solution of the base to the silica sol.

The Na content of the cationically modified silica sol is preferably <0.2% by weight of Na, particularly preferably <0.05% by weight and very particularly preferably <0.01% by weight of Na.

Further standard additives, such as corrosion inhibitors for the metals, such as for example benzotriazole amine, may be added to the composition according to the invention.

Moreover, complexing agents for the metals, which make the metals water-soluble, such as for example citric acid, citrates, amino acids, aspartic acids, tartaric acid, succinic acid, and/or the alkali metal salts thereof, may be added to the composition according to the invention. Preferred alkali metal salts are Na-free.

The invention also relates to a process for producing the composition according to the invention, characterized in that a cationically modified silica sol containing 1 to 21.5% by weight of cationically modified SiO₂ particles with a mean particle size of 12 to 300 nm and a pH of 2.5 to 6 is mixed with 0.05 to 22% by weight of at least one oxidizing agent.

If H₂O₂ is used as oxidizing agent, it is preferably added immediately before the composition according to the invention is used to polish metal and metal/dielectric structures; sufficient mixing should be ensured. This can be achieved, for example, by using suitable mixing nozzles. Mixing directly at the location of use, i.e. just before the composition according to the invention is applied to the polishing pad as a ready-to-use polishing slurry, is preferred.

The invention also relates to the use of the compositions according to the invention as polishing slurry for polishing semiconductors, integrated circuits and microelectromechanical systems.

The metals which are to be polished are preferably Al, Ru, Pt, Ir, Cu and W and/or the alloys, carbides and/or carbonitrides thereof.

The dielectrics which are to be polished are preferably SiLK™, polyimides, fluorinated polyimides, diamond-like carbons, polyarylethers, polyarylenes, parylene N, cyclotenes, polynorbonenes, Teflon, silsesquioxanes, SiO₂ glass or SiO₂ glass as the main component together with the additional components fluorine, phosphorus, carbon and/or boron. The barrier layers which are to be polished are preferably layers of Ta, TaSi, TaN, TaSiN, Ti, TiN, WN, WSiN, SiC, silicon oxynitride, silicon oxycarbide, silicon oxycarbonitride and/or Si₃N₄.

The invention is further illustrated but is not intended to be limited by the following examples in which all parts and percentages are by weight unless otherwise specified.

### EXAMPLES

Production of the Silica Sols

a) Acidic Silica Sol with a Mean Particle Size of 78 nm

The silica sol used was produced in the following way: 2.25 kg Al₂(OH)₅Cl.2-3H₂O and 0.560 kg of acetic acid (98% strength) were added to 18 kg of water. Then, 21 kg of silica sol Levasil® 50/50%, (Bayer AG, mean particle size 75 nm, solid content 50% by weight) were added. The pH was 3.8.

b) Acidic, Low-Sodium Silica Sol with a Mean Particle Size of 78 nm

The silica sol used was produced as follows: 2.25 kg of Al₂(OH)₅Cl.2-3H₂O and 0.560 kg of acetic acid (98% strength) were added to 4 kg of water. Then, 35 kg of silica sol Levasil® 50/30% with an Na content of <100 ppm (Bayer AG, mean particle size 78 nm, solids content 30% by weight) were added. The pH of this acidic sol was 3.8.

c) Acidic, Low-Sodium Silica Sol with a Mean Particle Size of 30 nm

The silica sol used was produced as follows: 2.25 kg of Al₂(OH)₅Cl.2-3H₂O and 0.560 kg of acetic acid (98% strength) were added to 4 kg of water. Then, 35 kg of silica sol Levasil® 100K/30% with an Na content of <100 ppm (Bayer AG, mean particle size 78 nm, solids content 30% by weight) were added. The pH of this acidic sol was 3.7.

Polishing Experiments

The polishing experiments were carried out using the polishing machine IPEC₃₇₂M produced by Westech, USA. The polishing parameters are listed in Table 1.150 mm wafers with coatings of Cu, Ta and SiO₂ were polished. Cu and Ta were deposited using a PVD (physical vapour deposition) process, and the SiO₂ was produced by oxidization of the Si wafer.

TABLE 1

| Polishing machine: IPEC | Polishing parameters | Polishing parameters |
|---|---|---|
| 372 M | A | B |
| Working wheel | 42 rpm | 30 rpm |
| (polishing pad) | | |
| rotational speed | | |
| Polishing head (wafer) | 45 rpm | 35 rpm |
| rotational speed | | |
| Applied pressure | 34.5 kPa (5.0 psi) | 34.5 kPa (5.0 psi) |
| Back-surface pressure | 13.8 kPa (2.0 psi) | 27.6 kPa (4.0 psi) |
| Slurry flow rate | 150 ml/min | 150 ml/min |
| Polishing pad | Rodel Politex | Rodel IC 1400 |
| | Regular E. ™ | |

### Example 1

In this series of tests, polishing slurries containing 0, 3, 5, 7 and 10% by volume of H₂O₂ were produced using silica sols as described in Example A. The SiO₂ content was in each case 10% by weight.

To make up one litre of polishing slurry containing 10% by weight of SiO₂ and 10% by volume of H₂O₂, the procedure was as follows:

300 ml of a 30% by weight SiO₂-containing silica sol (ζ=1.19 g/cm³) were diluted with 270 ml of distilled water with stirring. Then, 430 ml of 30% strength H₂O₂ solution (30% strength by weight solution, J. T. Baker, VLSI Grade) were added (ζ=1.11 g/cm³) and stirring was continued for 10 min. The density of the polishing slurry was approx. 1.1 g/cm³. The density of pure H₂O₂ is 1.41 g/cm³.

The polishing slurries containing 0, 3, 5 and 7% by volume of H₂O₂ were produced in the same way.

After production of the polishing slurries, the wafers were immediately polished using set of polishing parameters A. The results are listed in Table 2.

TABLE 2

| H₂O₂ | Removal rate | | | | | |
|---|---|---|---|---|---|---|
| Concentration | [Å/min] | | | Cu:Ta | Cu:oxide | Ta:oxide |
| [Vol.- %] | Cu | Ta | SiO₂ | Selectivity | selectivity | selectivity |
| 0 | 24 | — | — | — | — | — |
| 3 | 3406 | 100 | 60 | 34 | 57 | 1.7 |
| 5 | 5000 | 131 | 67 | 38 | 74 | 2.0 |
| 7 | 5820 | 140 | 69 | 42 | 84 | 2.0 |
| 10 | 7360 | 86 | 64 | 86 | 115 | 1.3 |

### Example 2

In this series of tests, polishing slurries containing 0, 3, 5, 7, 10 and 15% by volume of H₂O₂ were produced using silica sols in accordance with Example a) using the same procedure as that described in Example 1. The abrasive content was in each case 10% by weight. Silica sols with a mean particle diameter of 30 nm and 15 nm continued to be used (Levasil® 100 S/30% and Levasil® 200 S/30%, Bayer AG).

After production of the polishing slurries, the wafers were immediately polished using set of polishing parameters B. The results are listed in Table 3.

TABLE 3

| H₂O₂ | | | |
|---|---|---|---|
| Concentration | Removal rate | | |
| [Vol.-%] | [Å/min] | | |
| Silica sol | 78 nm | 30 nm | 15 nm |
| 0 | 264 | 208 | 164 |
| 3 | 1937 | 3505 | 2104 |
| 5 | 2920 | 4041 | 3811 |
| 7 | 3762 | 6193 | 4365 |
| 10 | 4968 | 8078 | 3926 |
| 15 | 8787 | 7055 | 3418 |

### Example 3

The static etch rate (SER) of Cu was determined for a polishing slurry containing 10% by weight of abrasive and various H₂O₂ contents. A low-sodium silica sol with a mean particle size of 30 nm in accordance with Example c) was used. Only the liquid phase is responsible for the purely chemical attack of the polishing slurry on the Cu. To rule out any possible influence from the silica sol particles (coverage of the Cu surface with particles), the silica sol was centrifuged. The solids content remaining in the liquid phase of the silica sol was approx.1%. The missing solids volume was replaced by demineralized water. The polishing slurry was made up using this modified silica sol. The results are listed in Table 4.

TABLE 4

| Content | | Solution | | | | SER |
|---|---|---|---|---|---|---|
| H₂O₂ | H₂O₂ | H₂O₂, 30% | Silica | | | |
| [% by | [% by | by weight | sol | H₂O | Total sol. | |
| weight] | volume] | [g] | [g] | [g] | [g] | nm |
| 0 | 0.00 | 0.00 | 4.76 | 15.24 | 20 | 5 |
| 3 | 2.11 | 2.00 | 4.76 | 13.24 | 20 | 11 |
| 5 | 3.55 | 3.33 | 4.76 | 11.91 | 20 | 8 |
| 7 | 5.01 | 4.67 | 4.76 | 10.57 | 20 | 5 |
| 10 | 7.24 | 6.67 | 4.76 | 8.57 | 20 | 2 |
| 14 | 10.30 | 9.33 | 4.76 | 5.91 | 20 | 2 |

Although the invention has been described in detail in the foregoing for the purpose of illustration, it is to be understood that such detail is solely for that purpose and that variations can be made therein by those skilled in the art without departing from the spirit and scope of the invention except as it may be limited by the claims.

What is claimed is:

1. Composition containing 2.5 to 70% by volume of a 30% by weight cationically modified silica sol, the cationically modified SiO₂ particles of which have a mean particle size of 12 to 300 nm, and 0.05 to 22% by weight of at least one oxidizing agent, with a pH of from 2.5 to 6.

2. Composition according to claim 1, wherein the cationically modified silica sol is obtainable by surface modification of unmodified silica sols with soluble, trivalent or tetravalent metal oxides, metal oxychlorides, metal oxyhydrates, metal nitrates, metal sulphates, metal oxysulphates and/or metal oxalates.

3. Composition according to claim 1, containing 1 to 21.5% by weight of cationically modified SiO₂ particles.

4. Composition according to claim 1, wherein the cationically modified SiO₂ particles have a bimodal particle size distribution, with the maximum A of the bimodal particle size distribution lying in the range from 10-100 nm, and the maximum B lying in the range from 40-300 nm, and the maximum A+10 nm<maximum B.

5. Composition according to claim 1, containing 0.05 to 22% by weight of an oxidizing agent.

6. Composition according to claim 1, containing from 3 to 15% by volume of hydrogen peroxide.

7. Composition according to claim 1, containing 0.1 to 6% by volume of ammonia peroxodisulphate.

8. A method of preparing metal and metal/dielectric structures comprising polishing said metal and metal/dielectric structures with the composition according to claim 1.

9. The method according to claim 8, wherein the metals are Al, Ru, Pt, Ir, Cu and/or W and/or the alloys, carbides and/or carbonitrides thereof.

10. The method according to claim 8, wherein the dielectrics are SiLK™, polyimides, fluorinated polyimides, diamond-like carbons, polyarylethers, polyarylenes, parylene N, cyclotenes, polynorbonenes, Teflon, silsesquioxanes, SiO₂ glass or SiO₂ glass with additional components selected from the group consisting of fluorine, phosphorus, carbon andr boron.

11. A method of fabricating semiconductors, integrated circuits and microelectromechanical systems comprising polishing said semiconductors, integrated circuits and microelectromechanical systems with the composition according to claim 1.

12. Process for producing a composition according to claim 1, comprising mixing a cationically modified silica sol containing 1 to 21.5% by weight of cationically modified SiO₂ particles with a mean particle size of 12 to 300 nm and a pH of 2.5 to 6 with 0.05 to 22% by weight of at least one oxidizing agent.
